(19) United States
(12) Patent Application Publication
(10) Pub. No.: US 2025/0015229 A1
(43) Pub. Date: Jan. 9, 2025

(54) LIGHT-EMITTING ELEMENT

(71) Applicant: NICHIA CORPORATION, Tokushima (JP)

(72) Inventors: Hiroshi FUJIMOTO, Tokushima-shi (JP); Yuta MORI, Tokushima-shi (JP)

(21) Appl. No.: 18/756,654

(22) Filed: Jun. 27, 2024

(30) Foreign Application Priority Data
Jul. 7, 2023 (JP) 2023-112231

(51) Int. Cl. H01L 33/10; H01L 33/38

(52) U.S. Cl. CPC H01L 33/10; H01L 33/38

(57) ABSTRACT

A light-emitting element includes a semiconductor structure body, a light-transmissive conductive film, a light-transmissive insulating film provided with a plurality of first openings, and a light-reflective conductive film contacting the light-transmissive conductive film in the first openings. In a top view, the extending portions of a first semiconductor layer include end portions (the portion of the extending portion located closest to a side of a second outer peripheral portion), the light-transmissive conductive film includes outer edges facing the end portions of the extending portions in a second direction, respectively, the first openings are not located between a first outer peripheral portion and a first straight line passing through an outer edge closest to the second outer peripheral portion among the plurality of outer edges of the light-transmissive conductive film and extending in a first direction, and are located between the first straight line and the second outer peripheral portion.

### CROSS-REFERENCE TO RELATED APPLICATION

This application claims priority to Japanese Patent Application No. 2023-112231, filed on Jul. 7, 2023, the disclosure of which is hereby incorporated by reference in its entirety.

### TECHNICAL FIELD

The present disclosure relates to a light-emitting element.

### BACKGROUND

For example, Japanese Patent Publication No. 2016-143682 discloses a configuration in which a plurality of n-dot electrodes are disposed along a long side of a light-emitting element having a rectangular shape in a top view.

### SUMMARY

An object of the present disclosure is to provide a light-emitting element that can reduce unevenness in a current density distribution.

According to an aspect of the present disclosure, a light-emitting element includes a semiconductor structure body including a first semiconductor layer including a first region and a second region located above inward of the first region in a top view, an active layer disposed above the second region, and a second semiconductor layer disposed above the active layer, the first region including a first outer peripheral portion and a second outer peripheral portion extending in a first direction, a third outer peripheral portion and a fourth outer peripheral portion extending in a second direction orthogonal to the first direction, and a plurality of extending portions extending in the second direction from the first outer peripheral portion and being located distance away from each other in the first direction, each of the first outer peripheral portion and the second outer peripheral portion having a length in the first direction longer than a length in the second direction of each of the third outer peripheral portion and the fourth outer peripheral portion; a light-transmissive conductive film disposed above the second semiconductor layer; a light-transmissive insulating film disposed above the light-transmissive conductive film and provided with a plurality of first openings located above the light-transmissive conductive film; a light-reflective conductive film disposed above the light-transmissive insulating film and being in contact with the light-transmissive conductive film in the first opening; a first electrode layer in contact with an extending portion of the plurality of extending portions; and a second electrode layer in contact with the light-reflective conductive film. In a top view, each of the plurality of extending portions includes an end portion that is the portion of the extending portion and located closest to a side of the second outer peripheral portion. In a top view, the light-transmissive conductive film includes a plurality of outer edges facing the end portions of the plurality of extending portions in the second direction, respectively, and located distance away from each other in the first direction. In a top view, the plurality of first openings are not located between the first outer peripheral portion and a first straight line passing through an outer edge closest to the second outer peripheral portion among the plurality of outer edges of the light-transmissive conductive film and extending in the first direction, and are located between the first straight line and the second outer peripheral portion.

The present disclosure can provide a light-emitting element in which unevenness in a current density distribution can be reduced.

### BRIEF DESCRIPTION OF DRAWINGS

FIG. 1 is a schematic a top view of a light-emitting element of an embodiment.

FIG. 2A is an enlarged schematic a top view of a region in FIG. 1 where a second external electrode layer is disposed.

FIG. 2B is an enlarged schematic a top view of a region in FIG. 1 where a first external electrode layer is disposed.

FIG. 3 is a schematic cross-sectional view taken along line III-III in FIG. 1.

FIG. 4 is an enlarged schematic cross-sectional view of a part of FIG. 3.

FIG. 5A is a measurement image of an emission intensity distribution of a light-emitting element of a first comparative example.

FIG. 5B is a measurement image of an emission intensity distribution of a light-emitting element of a second comparative example.

FIG. 6A is a measurement image of an emission intensity distribution of a light-emitting element of a first example.

FIG. 6B is a measurement image of an emission intensity distribution of a light-emitting element of a second example.

FIG. 7 is a schematic a top view of the light-emitting element of the first comparative example.

FIG. 8 is a schematic a top view of the light-emitting element of the second comparative example.

FIG. 9 is a schematic a top view of the light-emitting element of the first example.

FIG. 10 is a schematic a top view of a light-emitting element of a modified example of the embodiment.

### DETAILED DESCRIPTIONS

Embodiments are described below with reference to the drawings. In the drawings, the same constituent elements are denoted using the same reference signs. Note that the drawings schematically illustrate embodiments, and thus scales, intervals, positional relationships, and the like of members may be exaggerated, or some of the members are not illustrated in the drawings in some cases. As a cross-sectional view, an end view illustrating only a cut surface may be illustrated. In the cross-sectional view, hatching is not applied to the cross-section of a semiconductor structure body in order to make it easy to see the boundary of each layer of the semiconductor structure body.

In the following description, components having substantially the same function may be denoted by the same reference characters and a description thereof may be omitted. Terms indicating a specific direction or position (for example, “upper”, “upward, “lower”, “downward” and other terms including or related to those terms) may be used. However, these terms are used merely to make it easy to understand relative directions or positions in the referenced drawing. As long as the relative direction or position is the same as that described in the referenced drawing using the term such as “upper”, “upward”, “lower”, or “downward” in drawings other than the drawings of the present disclosure, actual products, and the like, components need not be arranged in the same manner as that in the referenced drawing. In the present specification, a positional relationship expressed by using the term “on” includes a case in which an object is in contact and also a case in which an object is not in contact but located above. Further, in the present specification, unless otherwise specified, meaning of “a member covers an object” includes a case in which the member is in contact with the object to be covered and directly covers the object to be covered, and a case in which the member is not in contact with the object to be covered and indirectly covers the object to be covered.

Drawings described below illustrate a first direction X, a second direction Y, and a third direction Z orthogonal to one another. In the description of the present specification, a direction of an arrow in the third direction Z is defined as an upward direction and a direction opposite to the direction of the arrow in the third direction Z is defined as a downward direction. A “straight line extending in the first direction X” is a straight line substantially parallel to the first direction X in a top view, and a straight line deviated from the first direction X within a range of 3° is also included in the “straight line extending in the first direction X”. Similarly, a “straight line extending in the second direction Y” is a straight line substantially parallel to the second direction Y in a top view, and a straight line deviated from the second direction Y within a range of 3° is also included in the “straight line extending in the second direction Y”.

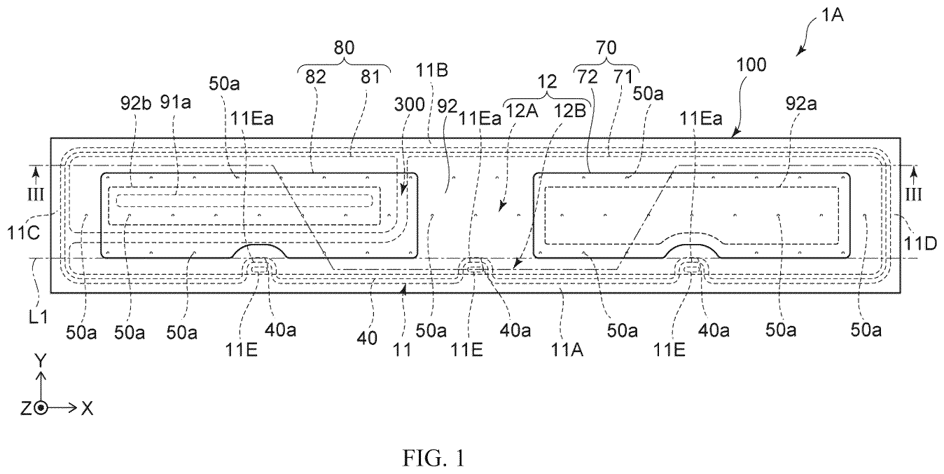

A light-emitting element 1A of an embodiment is described with reference to FIGS. 1, 2A, 2B, 3, and 4. The light-emitting element 1A of the embodiment includes a semiconductor structure body 100, a light-transmissive conductive film 40, a light-transmissive insulating film 50, a light-reflective conductive film 60, a first electrode layer 70, and a second electrode layer 80. Configurations are each described below.

### Semiconductor Structure Body

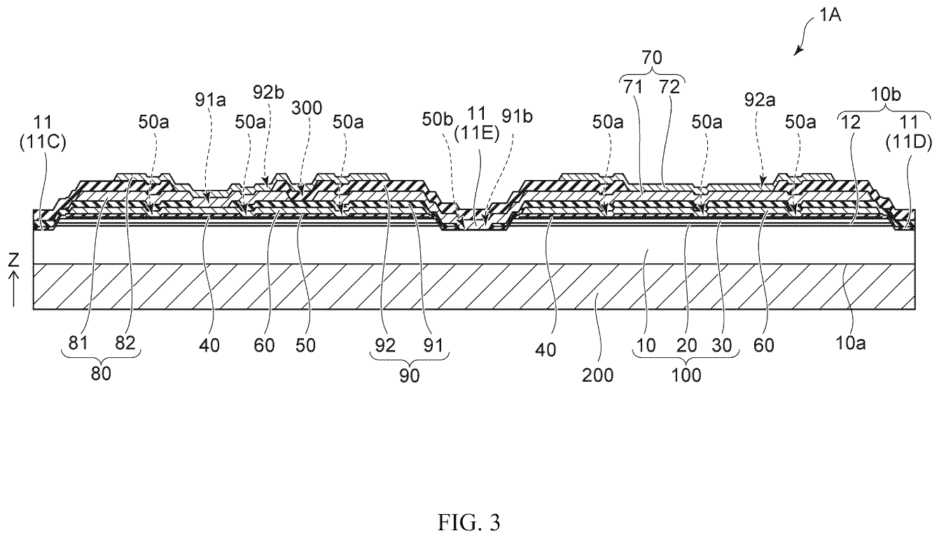

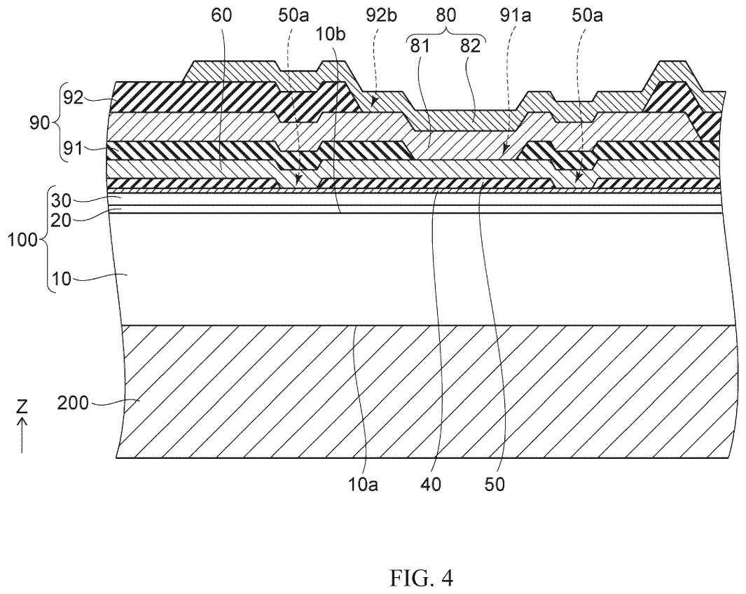

As illustrated in FIGS. 3 and 4, the semiconductor structure body 100 includes a first semiconductor layer 10, an active layer 20, and a second semiconductor layer 30. The semiconductor structure body 100 is formed of a nitride semiconductor. In the present specification, for example, it is assumed that the “nitride semiconductor” includes semiconductors having all compositions in which the composition ratios x and y are changed within the respective ranges in a chemical formula of InₓAl_{y}Ga_{1-x-y}N (0≤x≤1, 0≤y≤1, x+y≤1). In the above chemical formula, it is assumed that the “nitride semiconductor” includes a semiconductor further containing a group V element other than nitrogen (N), and a semiconductor further containing any of various elements added to control any of various physical properties such as a conductivity type.

The first semiconductor layer 10 includes a semiconductor layer containing n-type impurities. As illustrated in FIG. 1, the first semiconductor layer 10 includes a first region 11 and a second region 12 located inward of the first region 11 in a top view.

The first region 11 is exposed from the active layer 20 and the second semiconductor layer 30. The first region 11 includes a first outer peripheral portion 11A, a second outer peripheral portion 11B, a third outer peripheral portion 11C, and a fourth outer peripheral portion 11D. The first outer peripheral portion 11A and the second outer peripheral portion 11B extend in the first direction X. The third outer peripheral portion 11C and the fourth outer peripheral portion 11D extend in the second direction Y The length in the first direction X of each of the first outer peripheral portion 11A and the second outer peripheral portion 11B is longer than the length in the second direction Y of each of the third outer peripheral portion 11C and the fourth outer peripheral portion 11D. In a top view, the first outer peripheral portion 11A, the second outer peripheral portion 11, the third outer peripheral portion 11C, and the fourth outer peripheral portion 11D continuously surround the second region 12.

The first region 11 further includes a plurality of extending portions 11E. The plurality of extending portions 11E extend in the second direction Y from the first outer peripheral portion 11A toward the second outer peripheral portion 11B. The plurality of extending portions 11E are located distance away from each other in the first direction X. For example, FIG. 1 illustrates three extending portions 11E located distance away from each other in the first direction X. The number of the extending portions 11E may be two, or four or more. The extending portion 11E extends only from the first outer peripheral portion 11A and does not extend from the second outer peripheral portion 11B, the third outer peripheral portion 11C, and the fourth outer peripheral portion 11D.

In a top view, each of the plurality of extending portions 11E includes an end portion 11Ea that is the portion of the extending portion 11E located closest to the second outer peripheral portion 11B. The end portion 11Ea of the extending portion 11E is located closer to the first outer peripheral portion 11A than to a bisector extending in the first direction X that bisects the light-emitting element 1A into two parts adjacent one another in the second direction Y in a top view is.

As illustrated in FIGS. 3 and 4, the active layer 20 is disposed above the second region 12 of the first semiconductor layer 10. The active layer 20 is a light-emitting layer that emits light and has a multiple quantum well (MQW) structure including a plurality of barrier layers and a plurality of well layers, for example.

The second semiconductor layer 30 is disposed above the active layer 20. The second semiconductor layer 30 includes a semiconductor layer containing p-type impurities.

The first semiconductor layer 10 has a first surface 10a and a second surface 10b located on a side opposite to the first surface 10a in the third direction Z. The second surface 10b includes the first region 11 and the second region 12 described above. Light emitted by the active layer 20 is mainly extracted from the first surface 10a to the outside of the semiconductor structure body 100.

The light-emitting element 1A may include a substrate 200 that supports the semiconductor structure body 100. The semiconductor structure body 100 is disposed above the substrate 200 such that the first semiconductor layer 10 is located on the substrate 200 side in the third direction Z. The first surface 10a of the first semiconductor layer 10 is in contact with the substrate 200. As a material of the substrate 200, sapphire, spinel, GaN, SiC, ZnS, ZnO, GaAs, or Si can be used, for example. The light-emitting element 1A does not have to include the substrate 200.

### Light-Transmissive Conductive Film

As illustrated in FIGS. 3 and 4, the light-transmissive conductive film 40 is disposed above the second semiconductor layer 30. The light-transmissive conductive film 40 is in contact with the second semiconductor layer 30 and is electrically connected to the second semiconductor layer 30. The light-transmissive conductive film 40 is located above the second region 12 of the first semiconductor layer 10 and is not located above the first region 11 where the active layer 20 and the second semiconductor layer 30 are not disposed.

The light-transmissive conductive film 40 has transmissivity with respect to light emitted by the active layer 20. The transmittance of the light-transmissive conductive film 40 with respect to the peak wavelength of the light emitted by the active layer 20 is, for example, 60% or more. Thus, absorption of light in the light-transmissive conductive film 40 can be reduced. The light-transmissive conductive film 40 can diffuse a current supplied from the second electrode layer 80, in a planar direction of the second semiconductor layer 30. Thus, unevenness in a current density distribution can be reduced. As a material of the light-transmissive conductive film 40, indium tin oxide (ITO), zinc oxide (ZnO), or indium oxide (In₂O₃) can be used, for example.

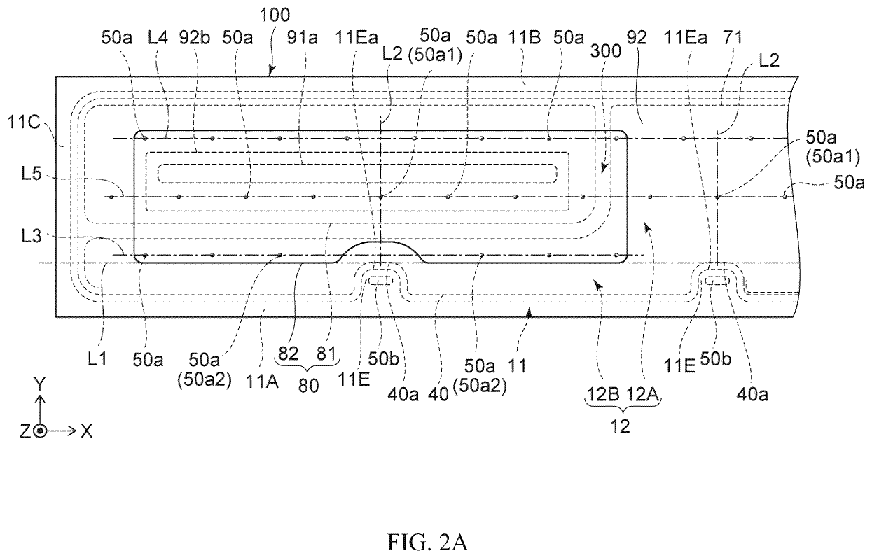

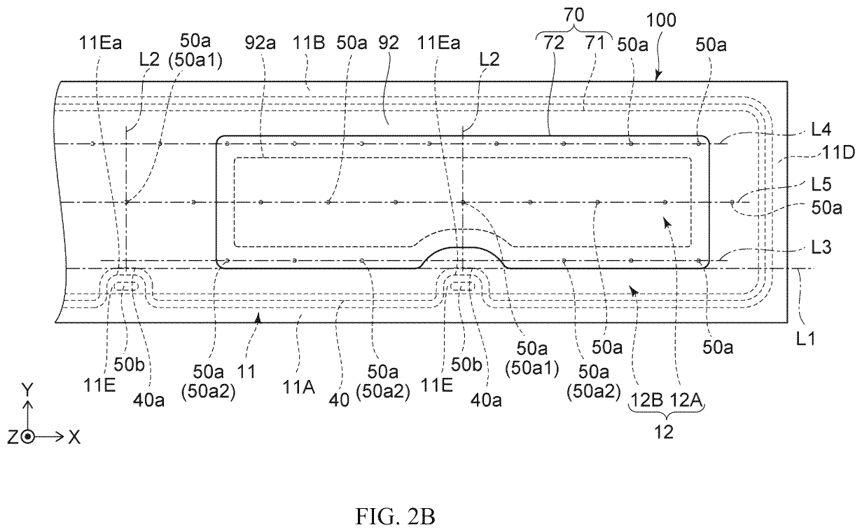

As illustrated in FIGS. 1, 2A, and 2B, in a top view, the light-transmissive conductive film 40 includes a plurality of outer edges 40a respectively facing the end portions 11Ea of the plurality of extending portions 11E of the first semiconductor layer 10 in the second direction Y The plurality of outer edges 40a are located distance away from each other in the first direction X. In a top view, the outer edge 40a of the light-transmissive conductive film 40 is located distance away from the end portion 11Ea of the extending portion 11E in the second direction Y.

### Light-Transmissive Insulating Film

As illustrated in FIGS. 3 and 4, the light-transmissive insulating film 50 is disposed above the light-transmissive conductive film 40. The light-transmissive insulating film 50 is provided with a plurality of first openings 50a located above the light-transmissive conductive film 40. In the first opening 50a, the light-transmissive conductive film 40 is not covered with the light-transmissive insulating film 50 and is exposed from the light-transmissive insulating film 50.

A part of the light emitted from the active layer 20 to the second semiconductor layer 30 side can be directed to the first surface 10a side of the first semiconductor layer 10, which is a main light extraction surface, by total reflection at an interface between the light-transmissive insulating film 50 and the light-transmissive conductive film 40. As the light-transmissive insulating film 50, a single layer film of a silicon oxide film can be used, for example. Alternatively, a dielectric multilayer film can be used as the light-transmissive insulating film 50.

### Light-Reflective Conductive Film

As illustrated in FIGS. 3 and 4, the light-reflective conductive film 60 is disposed above the light-transmissive insulating film 50. The light-reflective conductive film 60 is in contact with the light-transmissive conductive film 40 in the first opening 50a of the light-transmissive insulating film 50. In the first opening 50a, the light-reflective conductive film 60 is electrically connected to the light-transmissive conductive film 40.

Of the light emitted from the active layer 20 to the second semiconductor layer 30 side, light that does not satisfy a total reflection condition at the interface between the light-transmissive insulating film 50 and the light-transmissive conductive film 40 can be transmitted through the light-transmissive insulating film 50 and reflected by the light-reflective conductive film 60 toward the first surface 10a. The reflectance of the light-reflective conductive film 60 with respect to the peak wavelength of the light emitted by the active layer 20 is, for example, 60% or more. The light-reflective conductive film 60 preferably contains, for example, silver or aluminum. In addition, the light-reflective conductive film 60 may contain nickel, titanium, platinum, or the like. The light-reflective conductive film 60 may have a single layer structure or may have a layered structure in which a plurality of metal films are layered.

### First Electrode Layer

As illustrated in FIG. 3, the first electrode layer 70 is in contact with the extending portion 11E of the first semiconductor layer 10. The first electrode layer 70 is electrically connected to the first semiconductor layer 10 via the extending portion 11E. As a material of the first electrode layer 70, titanium, platinum, gold, aluminum, or copper can be used, for example. The first electrode layer 70 may have a single layer structure or may have a layered structure in which a plurality of metal films are layered.

The number of first openings 50a of the light-transmissive insulating film 50 is larger than the number of extending portions 11E of the first semiconductor layer 10. In other words, the number of portions where the light-reflective conductive film 60 and the light-transmissive conductive film 40 are in contact with each other is larger than the number of portions where the first electrode layer 70 and the first semiconductor layer 10 are in contact with each other.

### Second Electrode Layer

The second electrode layer 80 is in contact with the light-reflective conductive film 60. The second electrode layer 80 is electrically connected to the second semiconductor layer 30 via the light-reflective conductive film 60 and the light-transmissive conductive film 40. As a material of the second electrode layer 80, a material the same as or similar to the material of the first electrode layer 70 can be used, for example. The second electrode layer 80 may have a single layer structure or may have a layered structure in which a plurality of metal films are layered.

When a forward voltage is applied between the first electrode layer 70 and the second electrode layer 80 such that the potential of the second electrode layer 80 is higher than the potential of the first electrode layer 70, a current flows from the second electrode layer 80 to the first electrode layer 70 via the light-reflective conductive film 60, the light-transmissive conductive film 40, and the semiconductor structure body 100. When the current is supplied to the active layer 20, the active layer 20 emits light.

As illustrated in FIGS. 1, 2A, and 2B, in a top view, a straight line passing through the outer edge 40a closest to the second outer peripheral portion 11B of the first semiconductor layer 10 among the plurality of outer edges 40a of the light-transmissive conductive film 40 and extending in the first direction X is defined as a first straight line L1. When the positions of all the outer edges 40a in the second direction Y are the same, a straight line passing through any one of the outer edges 40a and extending in the first direction X is defined as the first straight line L1. A portion of the first straight line L1 overlaps the outer edge 40a of the light-transmissive conductive film 40 closest to the second outer peripheral portion 11B in a top view.

In a top view, the plurality of first openings 50a of the light-transmissive insulating film 50 are not located between the first straight line L1 and the first outer peripheral portion 11A, but are located between the first straight line L1 and the second outer peripheral portion 11B1. In a top view, the first openings 50a are located in a first partial region 12A of the second region 12. The first partial region 12A is surrounded by the first straight line L1, the second outer peripheral portion 11B, the third outer peripheral portion 11C, and the fourth outer peripheral portion 11D. The first openings 50a are not located in a second partial region 12B of the second region 12. The second partial region 12B is surrounded by the first straight line L1, the first outer peripheral portion 11A, the third outer peripheral portion 11C, and the fourth outer peripheral portion 11D. The end portions 11Ea of the extending portions 11E are located in the second partial region 12B. The area of the first partial region 12A is larger than the area of the second partial region 12B.

The first opening 50a serves as a current inflow portion to the semiconductor structure body 100, and the extending portion 11E serves as a current outflow portion from the semiconductor structure body 100. A current tends to concentrate on the first opening 50a relatively close to the extending portion 11E in a top view among the plurality of first openings 50a.

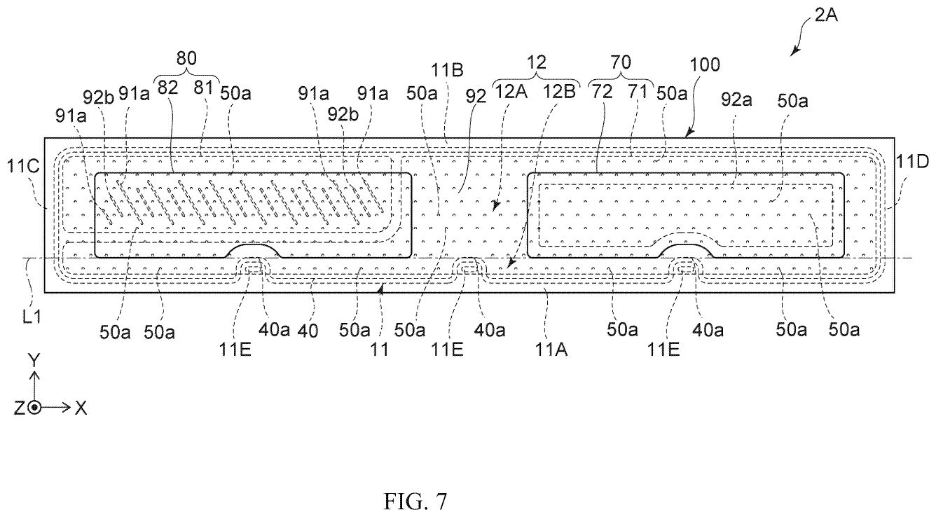

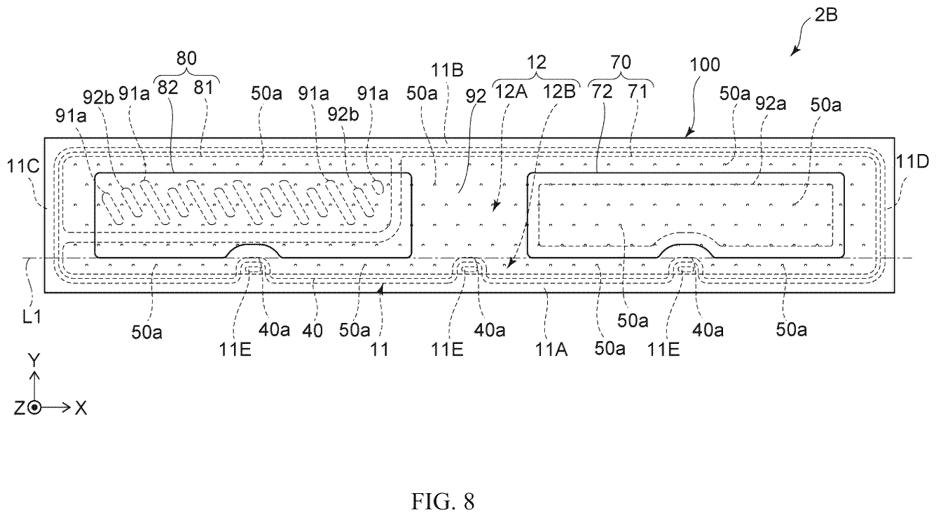

In comparative examples to be described below with reference to FIGS. 7 and 8, the first openings 50a are also located between the first straight line L1 and the first outer peripheral portion 11A. In such comparative examples, a current is likely to concentrate in portions of the semiconductor structure body 100 below the first openings 50a close to the extending portion 11E in a region between the first straight line L1 and the first outer peripheral portion 11A. In a region including the active layer 20 and the second semiconductor layer 30 of the semiconductor structure body 100, a portion where a current is concentrated has a relatively high emission intensity, which may cause unevenness in an emission intensity distribution of the light-emitting element.

According to the present embodiment, because the first opening 50a is not located between the first straight line L1 and the first outer peripheral portion 11A, the concentration of a current to the semiconductor structure body 100 below the first openings 50a close to the extending portions 11E can be reduced as compared with the comparative examples, and unevenness in a current density distribution in the semiconductor structure body 100 can be reduced. Thus, unevenness in an emission intensity distribution of the light-emitting element 1A can be reduced. The semiconductor structure body 100 below the first openings 50a close to the extending portions 11E is less likely to be thermally altered or destroyed.

According to the present embodiment, in a region between the first straight line L1 and the first outer peripheral portion 11A, where the emission intensity is likely to be high, the first openings 50a are not disposed and the light-transmissive insulating film 50 is in contact with the light-transmissive conductive film 40. Therefore, light with high emission intensity is totally reflected at the interface between the light-transmissive insulating film 50 and the light-transmissive conductive film 40, so that the luminance of light extracted from the first surface 10a can be increased.

As illustrated in FIGS. 2A and 2B, a straight line passing through the outer edge 40a of the light-transmissive conductive film 40 closest to the second outer peripheral portion 11B and extending in the second direction Y is defined as a second straight line L2. In a top view, a straight line extending in the first direction X near the first straight line L1 is defined as a third straight line L3. In a top view, the third straight line L3 is located between the first straight line L1 and the second outer peripheral portion 11B. The distance between the third straight line L3 and the first straight line L1 in the second direction Y is shorter than the distance between the third straight line L3 and the second outer peripheral portion 11B in the second direction Y.

Straight lines being further away from the first straight line L1 in the second direction Y than the third straight line L3 is and extending in the first direction X are defined as a fourth straight line L4 and a fifth straight line L5. In the second direction Y, the third straight line L3 is located closer to the first outer peripheral portion 11A than the fourth straight line L4 and the fifth straight line L5 are. In the second direction Y, the fourth straight line L4 is located closer to the second outer peripheral portion 11B than the third straight line L3 and the fifth straight line L5 are. In the second direction Y, the fifth straight line L5 is located between the third straight line L3 and the fourth straight line L4.

In a top view, a plurality of first openings 50a are located on the third straight line L3, a plurality of first openings 50a are located on the fourth straight line L4, and a plurality of first openings 50a are located on the fifth straight line L5.

The third straight line L3 is closer to the extending portion 11E in the second direction Y than the fourth straight line L4 and the fifth straight line L5 are. When the first opening 50a closest to the extending portion 11E in a top view among the plurality of first openings 50a is located on such a third straight line L3, a current is likely to concentrate in the semiconductor structure body 100 below the first opening 50a.

Therefore, among the plurality of first openings 50a, the first opening 50al closest to the extending portion 11E in a top view is preferably located on the second straight line L2 (except for an intersection point between the second straight line L2 and the third straight line L3). Thus, as compared with when the first opening 50a closest to the extending portion 11E in a top view is located on the third straight line L3, the concentration of a current to the semiconductor structure body 100 below the first opening 50al closest to the extending portion 11E can be reduced, so that unevenness in a current density distribution can be reduced. In the examples illustrated in FIGS. 2A and 2B, the first opening 50al closest to the extending portion 11E in a top view is located on the fifth straight line L5.

As illustrated in FIG. 3, the light-transmissive insulating film 50 is also disposed above the first region 11 of the first semiconductor layer 10. The light-transmissive insulating film 50 covers the upper surface of each of the first outer peripheral portion 11A, the second outer peripheral portion 11B, the third outer peripheral portion 11C, and the fourth outer peripheral portion 11D.

The light-transmissive insulating film 50 is provided with a second opening 50b located above the extending portion 11E. The light-transmissive insulating film 50 is provided with a plurality of second openings 50b respectively corresponding to the plurality of extending portions 11E. The first electrode layer 70 is in contact with the extending portion 11E in the second opening 50b.

In the configuration in which the first opening 50al closest to the extending portion 11E in a top view is located on the second straight line L2, a width of the second opening 50b in the first direction X is preferably larger than a width of the second opening 50b in the second direction Y As illustrated in FIGS. 1, 2A, and 2B, in a top view, the shape of the second opening 50b is an oval shape that is long in the first direction X. Alternatively, the shape of the second opening 50b may be a rectangular shape that is long in the first direction X in a top view. In a top view, the first opening 50al located on the second straight line L2 and closest to the extending portion 11E faces a long side portion of the second opening 50b having the above shape. Thus, as compared with when the first opening 50al closest to the extending portion 11E faces a corner portion of the second opening 50b, the concentration of a current to the semiconductor structure body 100 below the first opening 50al closest to the extending portion 11E can be reduced.

As described above, the second opening 50b that is long in the first direction X is likely to reduce an angle between a lateral surface of the light-transmissive insulating film 50 defining the second opening 50b and a lower surface of the light-transmissive insulating film 50, as compared with a second opening 50b that is circular or square in a top view. Thus, a thickness of the light-reflective conductive film 60 covering the lateral surface of the light-transmissive insulating film 50 can be easily increased, so that the reliability of the light-reflective conductive film 60 can be increased. According to the present embodiment, the angle between the lateral surface of the light-transmissive insulating film 50 defining the second opening 50b and the lower surface of the light-transmissive insulating film 50 can be in a range from 20° to 40°, for example.

Among the plurality of first openings 50a disposed on the third straight line L3 closer to the extending portion 11E in the second direction Y than the fourth straight line L4 and the fifth straight line L5 are, a plurality of first openings 50a2 are preferably closest to the respective extending portions 11E in a top view. The shortest distance between each of the plurality of first openings 50a2 and a corresponding one of the extending portions 11E in a top view is substantially an equal distance. Thus, the concentration of a current to the semiconductor structure body 100 below one first opening 50a2 can be reduced. Note that the “substantially equal distance” represents that the difference in distance is within 3 m.

As illustrated in FIG. 3, the first electrode layer 70 may include a first internal electrode layer 71 and a first external electrode layer 72, and the second electrode layer 80 may include a second internal electrode layer 81 and a second external electrode layer 82. As illustrated in FIG. 1, the first external electrode layer 72 and the second external electrode layer 82 are located distance away from each other in the first direction X with a bisector extending in the second direction Y that bisects the light-emitting element 1A into two parts adjacent one another in the first direction X interposed therebetween in a top view. The first external electrode layer 72 and the second external electrode layer 82 are electrically connected to wiring members of a wiring substrate, above which the light-emitting elements 1A are mounted, via conductive members such as solder.

The first internal electrode layer 71 is disposed above the second region 12 of the first semiconductor layer 10, in other words, in a region where the first semiconductor layer 10, the active layer 20, and the second semiconductor layer 30 are layered in the semiconductor structure body 100. The first internal electrode layer 71 is also disposed above the extending portion 11E of the first region 11 of the first semiconductor layer 10 and is in contact with the extending portion 11E. The first external electrode layer 72 is disposed above the first internal electrode layer 71 and is in contact with the first internal electrode layer 71. The first external electrode layer 72 is electrically connected to the first semiconductor layer 10 via the first internal electrode layer 71.

The second internal electrode layer 81 is disposed above the second region 12 of the first semiconductor layer 10 and is not disposed above the first region 11. The second internal electrode layer 81 is in contact with the light-reflective conductive film 60. The second external electrode layer 82 is disposed above the second internal electrode layer 81 and is in contact with the second internal electrode layer 81. The second external electrode layer 82 is electrically connected to the second semiconductor layer 30 via the second internal electrode layer 81, the light-reflective conductive film 60, and the light-transmissive conductive film 40.

As illustrated in FIG. 1, among the plurality of first openings 50a of the light-transmissive insulating film 50, the number of the first openings 50a overlapping the first external electrode layer 72 and the second external electrode layer 82 in a top view is preferably larger than the number of the first openings 50a not overlapping the first external electrode layer 72 and the second external electrode layer 82. Thus, heat due to light emission of the active layer 20 can be easily dissipated to the wiring substrate or the like, above which the light-emitting elements 1A are mounted, via the light-transmissive conductive film 40, the light-reflective conductive film 60 in contact with the light-transmissive conductive film 40 in the first openings 50a, the first electrode layer 70, and the second electrode layer 80. The first internal electrode layer 71 is not in contact with the light-reflective conductive film 60, but is disposed above the light-reflective conductive film 60 with an insulating film to be described below therebetween, and heat is transferred from the light-reflective conductive film 60 to the first internal electrode layer 71 via the insulating film.

In particular, because the temperature is likely to increase in a region close to the extending portion 11E where the emission intensity is likely to increase, all of the plurality of first openings 50a located on the third straight line L3 close to the extending portion 11E among the plurality of first openings 50a preferably overlap with the first external electrode layer 72 or the second external electrode layer 82 in a top view. Thus, heat due to light emission of the active layer 20 can be effectively and easily dissipated.

In a top view, the plurality of first openings 50a are not preferably located in a region 300 between the first internal electrode layer 71 and the second internal electrode layer 81 so that heat due to light emission of the active layer 20 can be efficiently transferred to the first internal electrode layer 71 or the second internal electrode layer 81 formed of a metal material having higher thermal conductivity than the insulating film.

At a corner portion of the light-emitting element 1A in a top view, light emitted from the active layer 20 toward the first surface 10a or the lateral surface of the first semiconductor layer 10 is likely to be reflected by the first surface 10a or the lateral surface thereof and return into the semiconductor structure body 100.

Therefore, as illustrated in FIG. 2A, in a top view, a first opening 50a located closest to the third outer peripheral portion 11C among the plurality of first openings 50a located on the third straight line L3 and a first opening 50a located closest to the third outer peripheral portion 11C among the plurality of first openings 50a located on the fourth straight line L4 are preferably located further away from the third outer peripheral portion 11C in the first direction X than a first opening 50a located closest to the third outer peripheral portion 11C among the plurality of first openings 50a located on the fifth straight line L5 is. In other words, the first opening 50a is not located near two corner portions closer to the third outer peripheral portion 11C in a top view. Thus, return light reflected at the two corner portions on the third outer peripheral portion 11C side is totally reflected at the interface between the light-transmissive insulating film 50 and the light-transmissive conductive film 40, so that the luminance of light extracted from the first surface 10a can be increased.

Similarly, as illustrated in FIG. 2B, in a top view, a first opening 50a located closest to the fourth outer peripheral portion 11D among the plurality of first openings 50a located on the third straight line L3 and a first opening 50a located closest to the fourth outer peripheral portion 11D among the plurality of first openings 50a located on the fourth straight line L4 are preferably located further away from the fourth outer peripheral portion 11D in the first direction X than a first opening 50a located closest to the fourth outer peripheral portion 11D among the plurality of first openings 50a located on the fifth straight line L5 is. In other words, the first opening 50a is not located near two corner portions closer to the fourth outer peripheral portion 11D in a top view. Thus, return light reflected at the two corner portions closer to the fourth outer peripheral portion 11D is totally reflected at the interface between the light-transmissive insulating film 50 and the light-transmissive conductive film 40, so that the luminance of light extracted from the first surface 10a can be increased.

As illustrated in FIGS. 3 and 4, the light-emitting element 1A may further include an insulating film 90 disposed above the first internal electrode layer 71 and the second internal electrode layer 81. For example, the insulating film 90 may include a first insulating film 91 and a second insulating film 92. As the first insulating film 91 and the second insulating film 92, a silicon oxide film can be used, for example.

The first insulating film 91 is disposed above the light-transmissive insulating film 50 and the light-reflective conductive film 60. The first insulating film 91 is provided with a fifth opening 91a located above the light-reflective conductive film 60. The second internal electrode layer 81 is in contact with the light-reflective conductive film 60 in the fifth opening 91a of the first insulating film 91.

The first insulating film 91 is provided with a sixth opening 91b located above the extending portion 11E and continuous with the second opening 50b of the light-transmissive insulating film 50. The first internal electrode layer 71 is in contact with the extending portion 11E in the sixth opening 91b of the first insulating film 91 and in the second opening 50b of the light-transmissive insulating film 50.

In the third direction Z, the first insulating film 91 is disposed between the light-reflective conductive film 60 and the second internal electrode layer 81 and between the light-reflective conductive film 60 and the first internal electrode layer 71.

The second insulating film 92 is disposed above the first insulating film 91, above the first internal electrode layer 71, and above the second internal electrode layer 81. The second insulating film 92 is disposed in the region 300 between the first internal electrode layer 71 and the second internal electrode layer 81 in a top view.

The second insulating film 92 is provided with a third opening 92a located above the first internal electrode layer 71. The first external electrode layer 72 is disposed above the second insulating film 92 and is in contact with the first internal electrode layer 71 in the third opening 92a.

The second insulating film 92 is provided with a fourth opening 92b located above the second internal electrode layer 81. The second external electrode layer 82 is disposed above the second insulating film 92, and is in contact with the second internal electrode layer 81 in the fourth opening 92b.

As illustrated in FIG. 4, an upper surface of the light-reflective conductive film 60 located at the first opening 50a of the light-transmissive insulating film 50 is more likely to be recessed than an upper surface of the light-reflective conductive film 60 located above the light-transmissive insulating film 50 where the first opening 50a is not located. The insulating film 90 layered above the light-reflective conductive film 60 is also likely to be recessed at a position above the recessed portion of the light-reflective conductive film 60. Therefore, when the plurality of first openings 50a of the light-transmissive insulating film 50 overlap an outer edge of the third opening 92a and an outer edge of the fourth opening 92b of the second insulating film 92 in a top view, lateral surfaces of the second insulating film 92 defining the third opening 92a and the fourth opening 92b are likely to be distorted so as to be recessed. When the lateral surface of the second insulating film 92 is distorted, the second insulating film 92 is likely to be cracked due to thermal stress.

Therefore, the plurality of first openings 50a of the light-transmissive insulating film 50 do not preferably overlap the outer edge of the third opening 92a and the outer edge of the fourth opening 92b of the second insulating film 92 in a top view. Thus, the second insulating film 92 is less likely to be cracked.

The following describes measurement results of emission intensity distributions of examples and comparative examples.

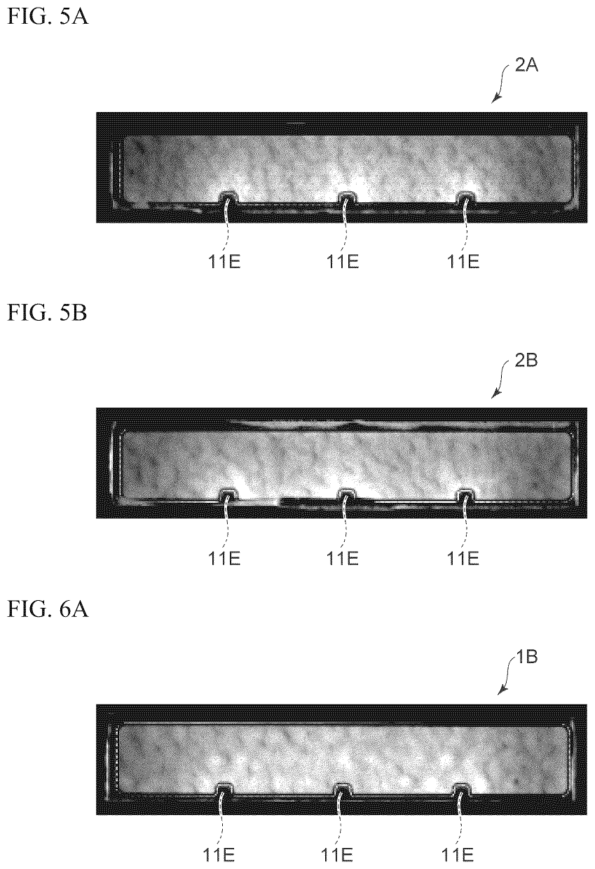

FIG. 5A is a measurement image of an emission intensity distribution of a light-emitting element 2A of a first comparative example illustrated in FIG. 7.

FIG. 5B is a measurement image of an emission intensity distribution of a light-emitting element 2B of a second comparative example illustrated in FIG. 8.

In the light-emitting element 2A of the first comparative example illustrated in FIG. 7 and the light-emitting element 2B of the second comparative example illustrated in FIG. 8, unlike in the light-emitting element 1A of the above-described embodiment, the first openings 50a are also located between the first straight line L1 and the first outer peripheral portion 11A in a top view. In the light-emitting element 2A of the first comparative example and the light-emitting element 2B of the second comparative example, the shapes and the numbers of the fifth openings 91a of the first insulating film 91 and the fourth openings 92b of the second insulating film 92 in a top view are different from those in the light-emitting element 1A of the embodiment; however, the design of the fifth opening 91a and the fourth opening 92b has almost no effect on reducing unevenness in an emission intensity distribution.

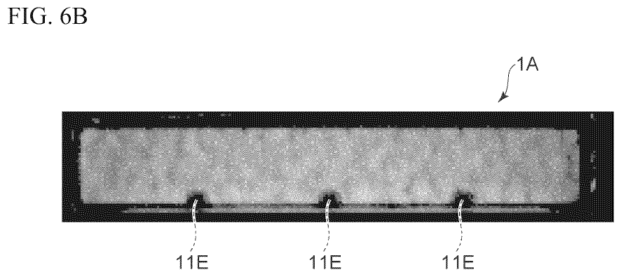

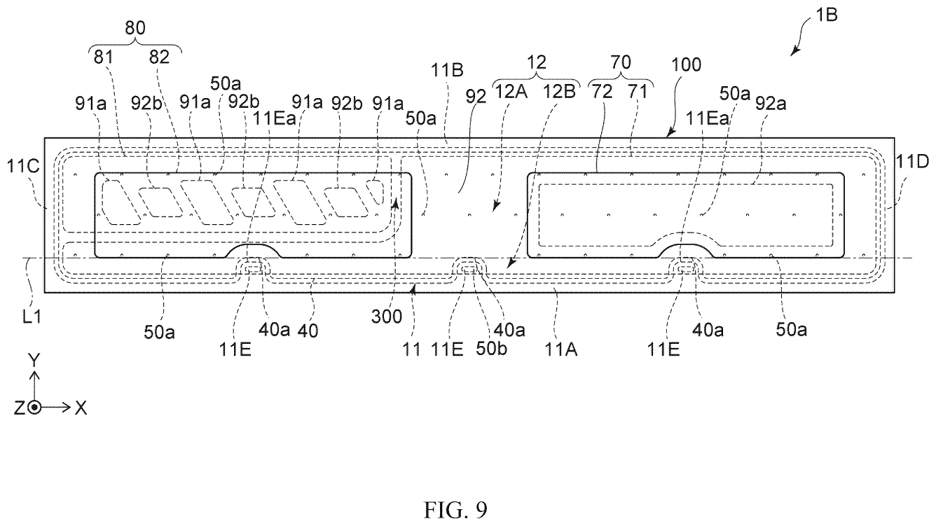

FIG. 6A is a measurement image of an emission intensity distribution of a light-emitting element 1B of a first example illustrated in FIG. 9.

In the light-emitting element 1B of the first example illustrated in FIG. 9, as in the light-emitting element 1A of the embodiment, no first opening 50a is located between the first straight line L1 and the first outer peripheral portion 11A in a top view. In the light-emitting element 1B of the first example, the shapes and the numbers of the fifth openings 91a of the first insulating film 91 and the fourth openings 92b of the second insulating film 92 in a top view are different from those in the light-emitting element 1A of the embodiment.

FIG. 6B is a measurement image of an emission intensity distribution of the light-emitting element 1A of a second example having the above-described configuration illustrated in FIGS. 1, 2A, 2B, 3, and 4.

FIGS. 5A, 5B, and 6A are measurement images of the emission intensity distribution of the light-emitting elements when a current of 70 mA flows. FIG. 6B is a measurement image of the emission intensity distribution of the light-emitting element when a current of 20 mA flows. In each of FIGS. 5A, 5B, 6A, and 6B, the emission intensity distribution is represented by a gray scale. In the gray scale, the higher the luminance, the stronger the emission intensity.

From the results shown in FIGS. 5A, 5B, 6A, and 6B, in the light-emitting element 1B of the first example and the light-emitting element 1A of the second example, unevenness in the emission intensity distribution is reduced more than in the light-emitting element 2A of the first comparative example and the light-emitting element 2B of the second comparative example. Because the emission intensity distribution is strongly correlated with a current density distribution, it can be said that the unevenness in the current density distributions of the light-emitting element 1B of the first example and the light-emitting element 1A of the second example can be reduce more than those of the light-emitting element 2A of the first comparative example and the light-emitting element 2B of the second comparative example.

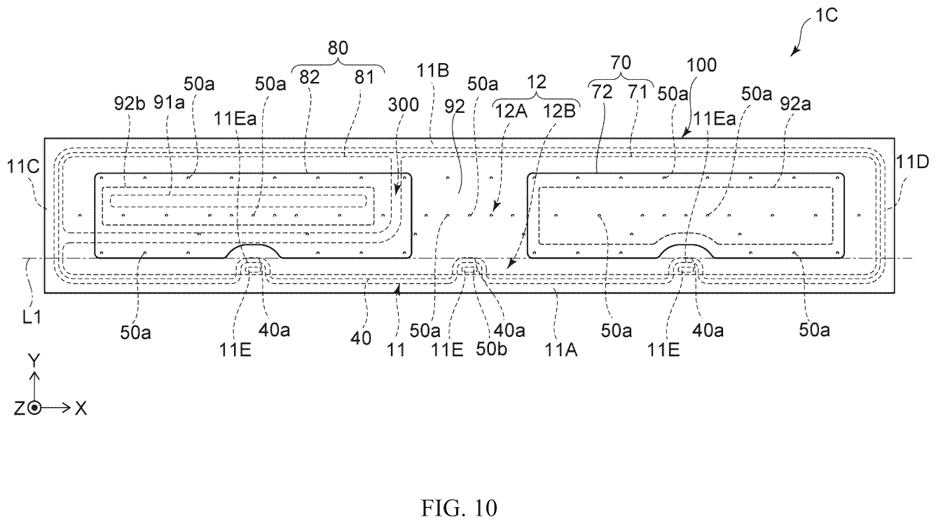

FIG. 10 is a schematic a top view of a light-emitting element 1C of a modified example of the embodiment.

Because the number of first openings 50a disposed around the extending portion 11E in the light-emitting element 1C illustrated in FIG. 10 is larger than that in the light-emitting element 1A illustrated in FIG. 1, unevenness in a current density distribution can be more easily reduced.

Embodiments of the present disclosure can include the following light-emitting elements.

The embodiments of the present invention have been described above with reference to specific examples. However, the present invention is not limited to these specific examples. All aspects that can be practiced by a person skilled in the art changing the design as appropriate based on the above-described embodiments of the present invention are also included in the scope of the present invention, as long as they encompass the spirit of the present invention. In addition, in the spirit of the present invention, a person skilled in the art can conceive of various modified examples and alterations, and those modified examples and alterations will also fall within the scope of the present invention.

What is claimed is:

1. A light-emitting element comprising:
a semiconductor structure body comprising:
a first semiconductor layer comprising a first region and a second region located inward of the first region in a top view,
an active layer disposed above the second region, and
a second semiconductor layer disposed above the active layer,
the first region comprising a first outer peripheral portion and a second outer peripheral portion extending in a first direction, a third outer peripheral portion and a fourth outer peripheral portion extending in a second direction orthogonal to the first direction, and a plurality of extending portions extending in the second direction from the first outer peripheral portion and located distance away from each other in the first direction, each of the first outer peripheral portion and the second outer peripheral portion having a length in the first direction longer than a length of each of the third outer peripheral portion and the fourth outer peripheral portion in the second direction;
a light-transmissive conductive film disposed above the second semiconductor layer;
a light-transmissive insulating film disposed above the light-transmissive conductive film and provided with a plurality of first openings, the first openings being located above the light-transmissive conductive film;
a light-reflective conductive film disposed above the light-transmissive insulating film and being in contact with the light-transmissive conductive film in the first openings;
a first electrode layer in contact with one of the plurality of extending portions; and
a second electrode layer in contact with the light-reflective conductive film, wherein
in the top view, each of the plurality of extending portions comprises an end portion that is the portion of the extending portion and located closest to the second outer peripheral portion,
in the top view, the light-transmissive conductive film comprises a plurality of outer edges located distance away from each other in the first direction, and respectively facing the end portions of the plurality of extending portions in the second direction, and
in the top view, the plurality of first openings are not located between the first outer peripheral portion and a first straight line that extends in the first direction and passes through an outer edge closest to the second outer peripheral portion among the plurality of outer edges of the light-transmissive conductive film, and the plurality of first openings are located between the first straight line and the second outer peripheral portion.

2. The light-emitting element according to claim 1, wherein one of the plurality of first openings closest to one of the plurality of extending portions in the top view is located on a second straight line extending in the second direction and passing through the outer edge of the light-transmissive conductive film closest to the second outer peripheral portion among the plurality of outer edges of the light-transmissive conductive film.

3. The light-emitting element according to claim 2, wherein
the light-transmissive insulating film is disposed above the first region of the first semiconductor layer and provided with a second opening located above one of the plurality of extending portions,
the first electrode layer is in contact with the one of the plurality of extending portions in the second opening, and
a width of the second opening in the first direction is larger than a width of the second opening in the second direction.

4. The light-emitting element according to claim 1, wherein
the first electrode layer comprises a first internal electrode layer in contact with one of the plurality of extending portions and a first external electrode layer disposed above the first internal electrode layer and being in contact with the first internal electrode layer,
the second electrode layer comprises a second internal electrode layer in contact with the light-reflective conductive film and a second external electrode layer disposed above the second internal electrode layer and being in contact with the second internal electrode layer, and
among the plurality of first openings, the number of first openings overlapping the first external electrode layer and the second external electrode layer in the top view is larger than the number of first openings not overlapping the first external electrode layer and the second external electrode layer.

5. The light-emitting element according to claim 4, wherein
in the top view, the plurality of first openings comprise the plurality of first openings located on a third straight line extending in the first direction and the plurality of first openings located on a fourth straight line extending in the first direction, and the third straight line is located closer to the first outer peripheral portion in the second direction than the fourth straight line is, and
all of the plurality of first openings located on the third straight line overlap with the first external electrode layer or the second external electrode layer in the top view.

6. The light-emitting element according to claim 1, wherein
the first electrode layer comprises a first internal electrode layer in contact with one of the plurality of extending portions and a first external electrode layer disposed above the first internal electrode layer and being in contact with the first internal electrode layer,
the second electrode layer comprises a second internal electrode layer in contact with the light-reflective conductive film and a second external electrode layer disposed above the second internal electrode layer and being in contact with the second internal electrode layer, and
in the top view, the plurality of first openings are not located between the first internal electrode layer and the second internal electrode layer.

7. The light-emitting element according to claim 1, wherein
in the top view, the plurality of first openings comprise the plurality of first openings located on a third straight line extending in the first direction, the plurality of first openings located on a fourth straight line extending in the first direction, and the plurality of first openings located on a fifth straight line extending in the first direction,
in the second direction, the third straight line is located closer to the first outer peripheral portion than the fourth straight line and the fifth straight line are, the fourth straight line is located closer to the second outer peripheral portion than the third straight line and the fifth straight line are, and the fifth straight line is located between the third straight line and the fourth straight line,
in the top view, one of the plurality of first openings located closest to the third outer peripheral portion among the plurality of first openings located on the third straight line and one of the plurality of first openings located closest to the third outer peripheral portion among the plurality of first openings located on the fourth straight line are located further away from the third outer peripheral portion in the first direction than one of the plurality of first openings located closest to the third outer peripheral portion among the plurality of first openings located on the fifth straight line is, and
in the top view, one of the plurality of first openings located closest to the fourth outer peripheral portion among the plurality of first openings located on the third straight line and one of the plurality of first openings located closest to the fourth outer peripheral portion among the plurality of first openings located on the fourth straight line are located further away from the fourth outer peripheral portion in the first direction than one of the plurality of first openings located closest to the fourth outer peripheral portion among the plurality of first openings located on the fifth straight line is.

8. The light-emitting element according to claim 1, wherein
the first electrode layer comprises a first internal electrode layer in contact with one of the plurality of extending portions,
the second electrode layer comprises a second internal electrode layer in contact with the light-reflective conductive film,
the light-emitting element further comprises an insulating film disposed above the first internal electrode layer and the second internal electrode layer and provided with a third opening and a fourth opening,
the first electrode layer further comprises a first external electrode layer disposed above the insulating film and being in contact with the first internal electrode layer in the third opening,
the second electrode layer further comprises a second external electrode layer disposed above the insulating film and being in contact with the second internal electrode layer in the fourth opening, and
in the top view, the plurality of first openings do not overlap an outer edge of the third opening and an outer edge of the fourth opening.

9. The light-emitting element according claim 2, wherein
the first electrode layer comprises a first internal electrode layer in contact with one of the plurality of extending portions and a first external electrode layer disposed above the first internal electrode layer and being in contact with the first internal electrode layer,
the second electrode layer comprises a second internal electrode layer in contact with the light-reflective conductive film and a second external electrode layer disposed above the second internal electrode layer and being in contact with the second internal electrode layer, and
among the plurality of first openings, the number of first openings overlapping the first external electrode layer and the second external electrode layer in the top view is larger than the number of first openings not overlapping the first external electrode layer and the second external electrode layer.

10. The light-emitting element according to claim 9, wherein
in the top view, the plurality of first openings comprise the plurality of first openings located on a third straight line extending in the first direction and the plurality of first openings located on a fourth straight line extending in the first direction, and the third straight line is located closer to the first outer peripheral portion in the second direction than the fourth straight line is, and
all of the plurality of first openings located on the third straight line overlap with the first external electrode layer or the second external electrode layer in the top view.

11. The light-emitting element according claim 3, wherein
the first electrode layer comprises a first internal electrode layer in contact with one of the plurality of extending portions and a first external electrode layer disposed above the first internal electrode layer and being in contact with the first internal electrode layer,
the second electrode layer comprises a second internal electrode layer in contact with the light-reflective conductive film and a second external electrode layer disposed above the second internal electrode layer and being in contact with the second internal electrode layer, and
among the plurality of first openings, the number of first openings overlapping the first external electrode layer and the second external electrode layer in the top view is larger than the number of first openings not overlapping the first external electrode layer and the second external electrode layer.

12. The light-emitting element according to claim 11, wherein
in the top view, the plurality of first openings comprise the plurality of first openings located on a third straight line extending in the first direction and the plurality of first openings located on a fourth straight line extending in the first direction, and the third straight line is located closer to the first outer peripheral portion in the second direction than the fourth straight line is, and
all of the plurality of first openings located on the third straight line overlap with the first external electrode layer or the second external electrode layer in the top view.

13. The light-emitting element according to claim 3, wherein
the first electrode layer comprises a first internal electrode layer in contact with one of the plurality of extending portions and a first external electrode layer disposed above the first internal electrode layer and being in contact with the first internal electrode layer,
the second electrode layer comprises a second internal electrode layer in contact with the light-reflective conductive film and a second external electrode layer disposed above the second internal electrode layer and being in contact with the second internal electrode layer, and
in the top view, the plurality of first openings are not located between the first internal electrode layer and the second internal electrode layer.

14. The light-emitting element according to claim 3, wherein
in the top view, the plurality of first openings comprise the plurality of first openings located on a third straight line extending in the first direction, the plurality of first openings located on a fourth straight line extending in the first direction, and the plurality of first openings located on a fifth straight line extending in the first direction,
in the second direction, the third straight line is located closer to the first outer peripheral portion than the fourth straight line and the fifth straight line are, the fourth straight line is located closer to the second outer peripheral portion than the third straight line and the fifth straight line are, and the fifth straight line is located between the third straight line and the fourth straight line,
in the top view, one of the plurality of first openings located closest to the third outer peripheral portion among the plurality of first openings located on the third straight line and one of the plurality of first openings located closest to the third outer peripheral portion among the plurality of first openings located on the fourth straight line are located further away from the third outer peripheral portion in the first direction than one of the plurality of first openings located closest to the third outer peripheral portion among the plurality of first openings located on the fifth straight line is, and
in the top view, one of the plurality of first openings located closest to the fourth outer peripheral portion among the plurality of first openings located on the third straight line and one of the plurality of first openings located closest to the fourth outer peripheral portion among the plurality of first openings located on the fourth straight line are located further away from the fourth outer peripheral portion in the first direction than one of the plurality of first openings located closest to the fourth outer peripheral portion among the plurality of first openings located on the fifth straight line is.

15. The light-emitting element according to claim 3, wherein
the first electrode layer comprises a first internal electrode layer in contact with one of the plurality of extending portions,
the second electrode layer comprises a second internal electrode layer in contact with the light-reflective conductive film,
the light-emitting element further comprises an insulating film disposed above the first internal electrode layer and the second internal electrode layer and provided with a third opening and a fourth opening,
the first electrode layer further comprises a first external electrode layer disposed above the insulating film and being in contact with the first internal electrode layer in the third opening,
the second electrode layer further comprises a second external electrode layer disposed above the insulating film and being in contact with the second internal electrode layer in the fourth opening, and
in the top view, the plurality of first openings do not overlap an outer edge of the third opening and an outer edge of the fourth opening.
